(19) United States
(12) Patent Application Publication
(10) Pub. No.: US 2026/0255822 A1
(43) Pub. Date: Aug. 27, 2026

(54) DISPLAY DEVICE, ELECTRONIC DEVICE, AND DRIVING METHOD OF DISPLAY DEVICE

(71) Applicant: SAMSUNG DISPLAY CO., LTD., YONGIN-SI (KR)

(72) Inventors: Se Wan SON, YONGIN-SI (KR); Min Woo WOO, YONGIN-SI (KR); Ki Hwan SEOK, YONGIN-SI (KR); Kwan Hee LEE, YONGIN-SI (KR); Seung Hyun LEE, YONGIN-SI (KR); HYERI CHO, YONGIN-SI (KR)

(21) Appl. No.: 19/374,242

(22) Filed: Oct. 30, 2025

(30) Foreign Application Priority Data
Feb. 21, 2025 (KR) 10-2025-0023211

(51) Int. Cl. H10K 59/131; G09G 3/3233; H10K 59/35

(52) U.S. Cl. CPC H10K 59/131; G09G 3/3233; H10K 59/353; G09G 2300/0426; G09G 2300/0465; G09G 2300/0819; G09G 2300/0852; G09G 2300/0861; G09G 2310/08; G09G 2320/0242; G09G 2330/021

(57) ABSTRACT

A display device includes a display area including a plurality of pixels, a peripheral area disposed outside the display area, and a gate line and a data line disposed in the display area. Each of the plurality of pixels includes a first circuit portion connected to the gate line and the data line, a second circuit portion connected to the first circuit portion, and a plurality of light-emitting elements connected to the second circuit portion and configured to emit light of different colors. The second circuit portion includes a plurality of control transistors connected between the first circuit portion and the plurality of light-emitting elements.

### CROSS-REFERENCE TO RELATED APPLICATIONS

This application claims priority under 35 U.S.C. § 119 to Korean Patent Application No. 10-2025-0023211 filed on February 21, 2025, the disclosure of which is incorporated by reference herein in its entirety.

### TECHNICAL FIELD

Embodiments of the present disclosure relate to a display device, an electronic device, and a driving method of the display device.

### DISCUSSION OF RELATED ART

A display device is a device configured to present images. Among display technologies, light-emitting diode (LED) displays are being developed as self-emissive displays.

Because LED displays are self-emissive, they do not require a separate backlight, which enables a thinner and lighter construction. Additionally, LED displays can achieve high performance characteristics, including low power consumption, high brightness, and fast response times.

Typically, an LED display includes a plurality of pixels, with each pixel including at least one pixel circuit portion formed from a plurality of transistors and at least one light-emitting element. The transistors in the pixel circuit portion are connected to various signal lines and voltage lines, including data lines, and are configured to deliver a driving current to the light-emitting element. The light-emitting element, having an anode and a cathode, receives the driving current through the anode connected to the transistor of the pixel circuit portion. The light-emitting element can emit light in specific wavelength ranges, such as red, green, or blue.

### SUMMARY

Embodiments of the present disclosure provide a display device having high resolution, and provide a display device in which degradation of display quality such as, for example, a rainbow phenomenon in which colors appear separated when moving images (e.g. a video) are displayed, is prevented.

According to an embodiment of the present disclosure, a display device, includes a display area including a plurality of pixels, a peripheral area disposed outside the display area, and a gate line and a data line disposed in the display area. Each of the plurality of pixels includes a first circuit portion connected to the gate line and the data line, a second circuit portion connected to the first circuit portion, and a plurality of light-emitting elements connected to the second circuit portion and configured to emit light of different colors. The second circuit portion includes a plurality of control transistors connected between the first circuit portion and the plurality of light-emitting elements.

In an embodiment, the display device further includes a plurality of emission control lines respectively connected to gate terminals of the plurality of control transistors, and an emission control circuit configured to generate an emission control signal and transmit the emission control signal to the plurality of emission control lines.

In an embodiment, the emission control circuit is configured to transmit the emission control signal, which is configured to turn on only a part of the plurality of control transistors, to the second circuit portion in a first sub-frame among a plurality of sub-frames included in one frame.

In an embodiment, the plurality of control transistors of the second circuit portion are configured to be turned on sequentially during the plurality of sub-frames of the one frame according to the emission control signal.

In an embodiment, the emission control circuit is disposed outside the display area.

In an embodiment, in one of the plurality of sub-frames, a first color which is an emission color of a first light-emitting element among the plurality of light-emitting elements that emits light in a first pixel among the plurality of pixels is different from a second color which is an emission color of a second light-emitting element among the plurality of light-emitting elements that emits light in a second pixel neighboring the first pixel.

In an embodiment, a third color which is an emission color of a third light-emitting element among the plurality of light-emitting elements that emits light in a third pixel neighboring the first pixel among the plurality of pixels is different from the first color and the second color.

In an embodiment, in each of the plurality of pixels, the second circuit portion is disposed adjacent to the first circuit portion in a plan view.

In an embodiment, each of the plurality of emission control lines extends parallel to the data line.

In an embodiment, the plurality of emission control lines pass through each of the plurality of pixels.

According to an embodiment of the present disclosure, an electronic device includes a processor and a display device connected to the processor. The display device includes a display area including a plurality of pixels, a peripheral area disposed outside the display area, and a gate line and a data line disposed in the display area. Each of the plurality of pixels include a first circuit portion connected to the gate line and the data line, a second circuit portion connected to the first circuit portion, and a plurality of light-emitting elements connected to the second circuit portion and configured to emit light of different colors. The second circuit portion includes a plurality of control transistors connected between the first circuit portion and the plurality of light-emitting elements.

In an embodiment, the electronic device further includes a plurality of emission control lines respectively connected to gate terminals of the plurality of control transistors, and an emission control circuit configured to generate an emission control signal and transmit the emission control signal to the plurality of emission control lines.

In an embodiment, the emission control circuit is configured to transmit the emission control signal, which is configured to turn on only a part of the plurality of control transistors, to the second circuit portion in a first sub-frame among a plurality of sub-frames included in one frame.

In an embodiment, the plurality of control transistors of the second circuit portion are configured to be turned on sequentially during the plurality of sub-frames of the one frame according to the emission control signal.

According to an embodiment of the present disclosure, a method of driving a display device includes emitting only a part of a plurality of light-emitting elements in one sub-frame among a plurality of sub-frames included in one frame. The display device includes a plurality of pixels, a gate line, and a data line. Each of the plurality of pixels includes a first circuit portion connected to the gate line and the data line, a second circuit portion connected to the first circuit portion, and the plurality of light-emitting elements connected to the second circuit portion and configured to emit light of different colors.

In an embodiment, the plurality of light-emitting elements emit light sequentially during the plurality of sub-frames included in the one frame.

In an embodiment, in one of the plurality of sub-frames, a first color which is an emission color of a first light-emitting element among the plurality of light-emitting elements that emits light in a first pixel among the plurality of pixels is different from a second color which is an emission color of a second light-emitting element among the plurality of light-emitting elements that emits light in a second pixel neighboring the first pixel.

In an embodiment, a third color which is an emission color of a third light-emitting element among the plurality of light-emitting elements that emits light in a third pixel neighboring the first pixel among the plurality of pixels is different from the first color and the second color.

In an embodiment, the second circuit portion includes a plurality of control transistors connected between the first circuit portion and the plurality of light-emitting elements, and emitting only the part of the plurality of light-emitting elements in the one sub-frame includes transmitting an emission control signal that turns on only a part of the plurality of control transistors to the plurality of control transistors.

In an embodiment, the electronic device further includes transmitting a gate signal to the gate line before transmitting the emission control signal to the plurality of control transistors.

According to embodiments of the present disclosure, a plurality of sub-pixels share a common pixel circuit portion, which may improve spatial efficiency and support higher display resolution. Additionally, by employing a time-division display method within each frame, embodiments may prevent degradation of display quality such as, for example, avoiding the rainbow phenomenon in which colors appear separated during the display of moving images (e.g., a video)..

### BRIEF DESCRIPTION OF THE DRAWINGS

The above and other features of the present disclosure will become more apparent by describing in detail embodiments thereof with reference to the accompanying drawings.

FIG. 1 is a layout diagram of a display device according to an embodiment.

FIG. 2 is a diagram illustrating a time division display method of an image of one frame of a display device according to an embodiment.

FIG. 3 is a circuit diagram of one pixel of a display device according to an embodiment.

FIG. 4 is a timing diagram of signals applied to the pixel shown in FIG. 3.

FIG. 5 is a diagram illustrating an image display method of sub-pixels according to signals applied to the pixel shown in FIG. 3 during one frame.

FIG. 6 illustrates sub-images displayed by a display device according to an embodiment during a plurality of sub-frames and an integrated image perceived by a user.

FIG. 7 is a plan view of one pixel of a display device according to an embodiment.

FIG. 8 is a cross-sectional view taken along the line A1-A2 of the display device shown in FIG. 7.

FIG. 9 is a block diagram of an electronic device according to an embodiment.

FIG. 10 is schematic diagrams of electronic devices according to various embodiments.

### DETAILED DESCRIPTION

Embodiments of the present disclosure will be described more fully hereinafter with reference to the accompanying drawings. Like reference numerals may refer to like elements throughout the accompanying drawings.

It will be understood that terms such as “comprise,” “include,” and “have,” when used herein, specify a presence of stated features, integers, steps, operations, elements, and/or components, but do not preclude the presence or addition of one or more other features, integers, steps, operations, elements, components, and/or groups thereof.

It will be understood that the terms “first,” “second,” “third,” etc. are used herein to distinguish one element from another, and the elements are not necessarily limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature’s relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ± 30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

Also, throughout the specification, when the term “in a plane” or “in a plan view” is used, it means when viewing the target portion from above, and may mean when viewing the target portion in a direction parallel to a third direction DR3 perpendicular to a first direction DR1 and a second direction DR2 in the drawings of this disclosure. Throughout the specification, when the term “in a cross-section” or “in a cross-sectional view” is used, it means when viewing a vertical cross-section of the target portion from the side, and may mean when viewing the target portion from a direction perpendicular to the third direction DR3 in the drawings of this disclosure.

Embodiments of the present disclosure relate to a display device in which multiple sub-pixels of different colors share a common pixel circuit portion, with individual sub-pixels selectively activated during different sub-frames of a display frame. This configuration allows the driving circuit to be simplified while maintaining high-quality image reproduction.

By using a first circuit portion shared by the plurality of sub-pixels to provide driving current, and a second circuit portion with separate control transistors connected to each sub-pixel, the display device can reduce circuit area while still delivering reliable current to each light-emitting element. This approach may improve spatial efficiency, and enable higher pixel density and higher resolution in the display area.

In addition, embodiments employ a time-division driving scheme in which only a portion of the sub-pixels emit light in each sub-frame. Through appropriate emission control signals, neighboring pixels can be arranged to display different colors during a given sub-frame, which may prevent color break-up effects or rainbow artifacts in moving images (e.g., video) and improve the visual quality perceived by the user.

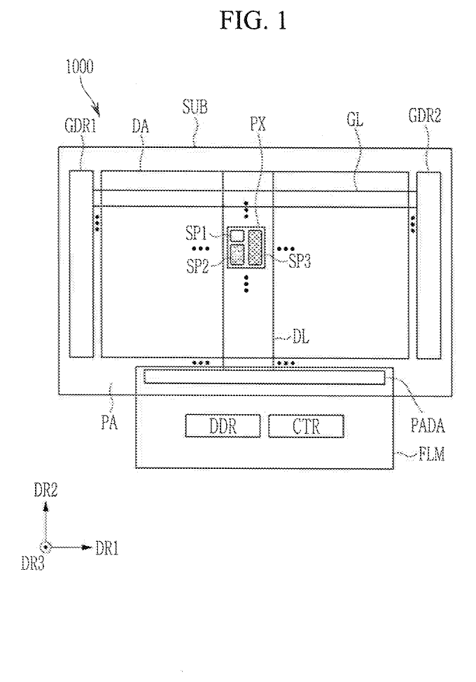

Referring to FIG. 1, a structure of a display device according to an embodiment will be described.

FIG. 1 is a layout diagram of a display device according to an embodiment.

Referring to FIG. 1, a display device 1000 according to an embodiment may include a display area DA in which an image is displayed, and a peripheral area PA disposed outside the display area DA. The display device 1000 includes a substrate SUB, and the display area DA and the peripheral area PA may be formed on the substrate SUB. The display device 1000 according to an embodiment may further include gate drivers GDR1 and GDR2, a data driver DDR, and a signal controller CTR.

The substrate SUB may have various planar shapes including, for example, a polygon like a rectangle, a circle, an ellipse, or an irregular shape. In an embodiment, the corners of the planar shape of the outer edge of the substrate SUB may form generally sharp angles or may be rounded. FIG. 1 shows an example where the outer edge of the substrate SUB is generally rectangular and the corners are right angles, however, embodiments are not necessarily limited thereto.

The display area DA may include a plurality of pixels PX, and a plurality of signal lines and a plurality of voltage lines connected to the plurality of pixels PX. Each pixel PX may include a pixel circuit portion and a plurality of sub-pixels SP1, SP2, and SP3. The pixel circuit portion may include a plurality of transistors and at least one capacitor.

The plurality of sub-pixels SP1, SP2, and SP3 included in one pixel PX may include a plurality of light-emitting elements. The plurality of light-emitting elements of the plurality of sub-pixels SP1, SP2, and SP3 included in one pixel PX may include two or more light-emitting elements configured to emit light of different colors. For example, the first sub-pixel SP1 may include a light-emitting element emitting light of a first color, the second sub-pixel SP2 may include a light-emitting element emitting light of a second color different from the first color, and the third sub-pixel SP3 may include a light-emitting element emitting light of a third color different from the first color and the second color. The plurality of sub-pixels SP1, SP2, and SP3 included in one pixel PX may be adjacent to each other and may emit light together to display a certain color, for example, a white image. The emission areas of the plurality of sub-pixels SP1, SP2, and SP3 may be areas where each of the plurality of light-emitting elements emits light. According to embodiments, unless otherwise specified, each sub-pixel SP1, SP2, SP3 may refer to an emission area where each light-emitting element emits light.

At least two of the plurality of sub-pixels SP1, SP2, and SP3 included in one pixel PX may have different planar areas. At least two of the plurality of sub-pixels SP1, SP2, and SP3 included in one pixel PX may have different planar shapes.

The plurality of light-emitting elements of the plurality of sub-pixels SP1, SP2, and SP3 included in one pixel PX may be connected to the pixel circuit portion included in the corresponding pixel PX.

In an embodiment, the pixel circuit portion may be configured to provide a driving current that is selectively delivered to each of the sub-pixels SP1, SP2, and SP3 in a time-divided manner, which may enable the respective light-emitting elements of different colors to emit light sequentially within a frame period. Such selective driving may support a compact circuit layout and may help suppress visual artifacts in moving images.

The plurality of sub-pixels SP1, SP2, and SP3 disposed on the substrate SUB may be arranged in various forms such as, for example, a stripe arrangement, a pentile arrangement, a diamond arrangement, a mosaic arrangement, or the like.

The plurality of pixel circuit portions of the plurality of pixels PX may be disposed on the substrate SUB with a regular arrangement form such as a matrix form. In the display device according to an embodiment, a plurality of pixel circuit portions arranged in the first direction DR1 to form one row is referred to as a pixel row, and a plurality of pixel circuit portions arranged in the second direction DR2 to form one column is referred to as a pixel column.

The plurality of signal lines of the display area DA may include gate lines GL and data lines DL connected to the pixel circuit portions. The gate lines GL may be connected to gate terminals of transistors included in the pixel circuit portions to transmit gate signals, and the data lines DL may be connected to source terminals or drain terminals of transistors included in the pixel circuit portions to transmit data voltages. Each of the gate lines GL may extend overall in the first direction DR1 to extend to the peripheral area PA adjacent to the left or right side of the display area DA, and each of the data lines DL may extend overall in the second direction DR2 to extend to the peripheral area PA adjacent to the upper or lower side of the display area DA.

The peripheral area PA may surround the display area DA. In an embodiment, the peripheral area PA may surround an entirety of the display area DA. The planar shape of the boundary between the display area DA and the peripheral area PA, that is, the planar shape of the outer edge of the display area DA, may be, for example, a polygon like a rectangle, a circle, an ellipse, or an irregular shape. In an embodiment, the corners of the planar shape of the outer edge of the display area DA may form generally sharp angles or may be rounded. FIG. 1 shows an example where the outer edge of the display area DA is generally rectangular and the corners are right angles, however, embodiments are not necessarily limited thereto.

The peripheral area PA may include gate drivers GDR1 and GDR2. The gate drivers GDR1 and GDR2 may be connected to the gate lines GL to apply gate signals to the gate lines GL. The gate drivers GDR1 and GDR2 may be disposed in the peripheral area PA to the left or right of the display area DA. FIG. 1 shows an example where a first gate driver GDR1 is disposed on the left side of the display area DA and a second gate driver GDR2 is disposed on the right side, but embodiments are not necessarily limited thereto. For example, in an embodiment, one of the first gate driver GDR1 and the second gate driver GDR2 may be omitted. The first gate driver GDR1 and the second gate driver GDR2 may include gate driving circuits that generate gate signals. The gate driving circuit corresponding to each pixel row may form a stage, and a plurality of stages may be arranged in order in the second direction DR2 in each of the first gate driver GDR1 and the second gate driver GDR2. The gate line GL of each pixel row may be connected to both the gate driving circuit of the first gate driver GDR1 and the gate driving circuit of the second gate driver GDR2 to receive gate signals, or may be connected to only one of them. According to an embodiment, the gate lines GL of the plurality of pixel rows may be alternately connected to the gate driving circuit of the first gate driver GDR1 and the gate driving circuit of the second gate driver GDR2 for each pixel row.

The peripheral area PA may further include a pad area PADA. The pad area PADA may be disposed in the peripheral area PA at the upper or lower side of the display area DA. The pad area PADA may include a plurality of conductive pads that are not covered by at least one insulation layer on the substrate SUB and are exposed. A circuit board or a circuit film may be attached to the pad area PADA. FIG. 1 shows an example where the display device 1000 further includes a circuit film FLM attached to the pad area PADA and electrically connected to the pads of the pad area PADA.

The data driver DDR and the signal controller CTR may be disposed on the circuit film FLM or on a circuit board connected to it, or may be disposed on the substrate SUB according to an embodiment. The data driver DDR may generate data signals and apply them to the data lines DL.

The signal controller CTR may be configured to receive input image signals and input control signals from an external source, process them, and generate data signals and control signals that can control the operation of the gate drivers GDR1 and GDR2 and the data driver DDR. The input control signals may include, for example, a vertical synchronization signal, a horizontal synchronization signal, a main clock signal, and a data enable signal, etc.. The control signals that the signal controller CTR transmits to the data driver DDR may include a horizontal synchronization start signal, a clock signal, and a line latch signal, etc., and the control signals that the signal controller CTR transmits to the gate drivers GDR1 and GDR2 may include, for example, a vertical synchronization start signal, an output enable signal, and a gate pulse signal, etc.

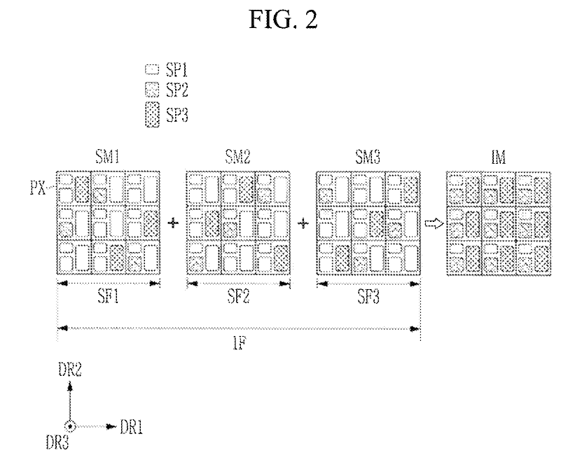

Referring to FIGS. 1 and 2, a method of driving a display device according to an embodiment, and a display device that may be driven by this method, is described.

FIG. 2 is a diagram illustrating a time division display method of an image of one frame of a display device according to an embodiment.

When input image signals and input control signals for one frame 1F are provided from an external source to the signal controller CTR, the plurality of pixels PX in the display area DA of the display device 1000 can display a plurality of sub-images SM1, SM2, and SM3 by dividing one frame 1F into a plurality of sub-frames SF1, SF2, and SF3, by the signal controller CTR, and the gate drivers GDR1 and GDR2 and the data driver DDR controlled by the signal controller CTR. The sub-images SM1, SM2, and SM3 of the plurality of sub-frames SF1, SF2, and SF3 of one frame 1F displayed consecutively in this way can be displayed successively and recognized by a user as an integrated image IM for the input image signal.

In an embodiment, by reusing the first circuit portion PX-C1 to control the driving current for multiple sub-pixels SP1, SP2, and SP3 within a single pixel PX, the system can more efficiently manage signal routing and reduce the overall circuit complexity. This arrangement may allow for sequential control of the individual sub-pixels during their corresponding sub-frames while preserving consistent luminance and color fidelity, supporting a compact circuit design that improves the available active area of the display.

FIG. 2 shows an example of dividing one frame 1F into three sub-frames SF1, SF2, and SF3 to display three sub-images SM1, SM2, and SM3, but the number of sub-frames of one frame 1F is not necessarily limited to this. For example, in an embodiment, the number of the plurality of sub-frames SF1, SF2, and SF3 included in one frame 1F may vary depending on the number of sub-pixels representing different colors included in one pixel PX. Herein, an example is described in which one pixel PX includes three sub-pixels SP1, SP2, and SP3, however, embodiments are not necessarily limited thereto.

According to an embodiment, only a part of the plurality of sub-pixels SP1, SP2, and SP3 included in one pixel PX may emit light in each sub-frame SF1, SF2, and SF3. For example, only one sub-pixel among the plurality of sub-pixels SP1, SP2, and SP3 included in one pixel PX may emit light in each sub-frame SF1, SF2, and SF3. In an embodiment, in each frame 1F, a sub-pixel SP1, SP2, or SP3 that emits light in one sub-frame SF1, SF2, or SF3 does not emit light in other sub-frames SF1, SF2, or SF3.

In addition, according to an embodiment, activating only a portion of the sub-pixels within each pixel PX during a given sub-frame may reduce instantaneous current load on the data line DL and the power supply lines. By lowering peak current demand, the overall power efficiency of the display device can be improved, while still achieving high-quality color reproduction across the entire frame.

The color of the emitting sub-pixel SP1, SP2, or SP3 of one pixel PX in each sub-frame SF1, SF2, or SF3 may be different from the color of at least one emitting sub-pixel SP1, SP2, or SP3 among the pixels PX neighboring that pixel PX. For example, if only the first sub-pixel SP1 emitting light of a first color is emitting in one pixel PX, at least one emitting sub-pixel of the plurality of pixels neighboring the above-mentioned pixel PX may be the second sub-pixel SP2 emitting light of a second color different from the first color or the third sub-pixel SP3 emitting light of a third color. For example, the color of the emitting sub-pixel in a pixel PX neighboring one pixel PX in the first direction DR1 may be different from the color of the emitting sub-pixel in that one pixel. The color of the emitting sub-pixel in a pixel PX neighboring one pixel PX in the second direction DR2 may be different from the color of the emitting sub-pixel in that one pixel.

Referring to FIG. 1, if the first sub-pixel SP1 is emitting in the central pixel PX, the sub-pixel emitting in a pixel PX neighboring the central pixel PX in the first direction DR1 or the second direction DR2 may be the second sub-pixel SP2 or the third sub-pixel SP3. On the other hand, if the first sub-pixel SP1 is emitting in the central pixel PX, the sub-pixel emitting in a pixel PX neighboring the central pixel PX in a diagonal direction different from the first direction DR1 and the second direction DR2 may be one of the first sub-pixel SP1, the second sub-pixel SP2, and the third sub-pixel SP3.

Each of the plurality of sub-pixels SP1, SP2, and SP3 included in one pixel PX may emit light in any one sub-frame SF1, SF2, or SF3 among the plurality of sub-frames SF1, SF2, and SF3 of one frame 1F. For example, referring to the central pixel PX shown in FIG. 2, the first sub-pixel SP1 may emit light in the first sub-frame SF1 among the plurality of sub-frames SF1, SF2, and SF3, the second sub-pixel SP2 may emit light in the second sub-frame SF2, and the third sub-pixel SP3 may emit light in the third sub-frame SF3. Eventually, during one frame 1F, all sub-pixels SP1, SP2, and SP3 of one pixel PX may emit light at least once, which may be recognized as an integrated image IM for one input image signal.

For each frame 1F, the plurality of sub-pixels SP1, SP2, and SP3 of each pixel PX may emit light at least once in at least one sub-frame SF1, SF2, or SF3.

The order in which the plurality of sub-pixels SP1, SP2, and SP3 included in each pixel PX emit light during a plurality of frames may be the same or different for two or more pixels PX. For example, if the plurality of sub-pixels SP1, SP2, and SP3 of one pixel PX emits light in the order of the first color, the second color, the third color, the first color, the second color, and the third color over a plurality of frames, the plurality of sub-pixels SP1, SP2, and SP3 of another pixel PX may also emit light in the order of the second color, the third color, the first color, the second color, the third color, and the first color over a plurality of frames.

In this way, since the colors of light displayed by the plurality of pixels PX displayed in each sub-frame SF1, SF2, and SF3 of one frame 1F are not the same but diverse, degradation of display quality such as a rainbow phenomenon in which colors appear separated can be prevented. For example, when the display device 1000 displays a fast-moving video, the occurrence of a rainbow phenomenon in which the colors of moving objects appear separated may be prevented.

For example, according to embodiments, for each frame 1F, the plurality of sub-pixels SP1, SP2, and SP3 of each pixel PX may emit light at least once in at least one sub-frame SF1, SF2, or SF3. The sequence in which the plurality of sub-pixels SP1, SP2, and SP3 of each pixel PX emit light across multiple frames may be the same or different for different pixels. For example, while one pixel PX may emit its sub-pixels in the order of a first color, second color, and third color across consecutive frames, a neighboring pixel may emit its sub-pixels in a different order, such as second color, third color, and first color. By varying the color emission patterns among neighboring pixels in each sub-frame of one frame, the overall image displayed by the plurality of pixels PX can achieve color diversity. This may prevent degradation of display quality, such as the rainbow phenomenon in which colors appear separated, for example, when displaying fast-moving video content.

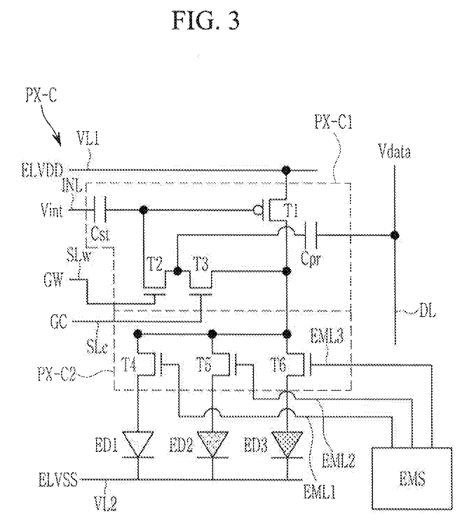

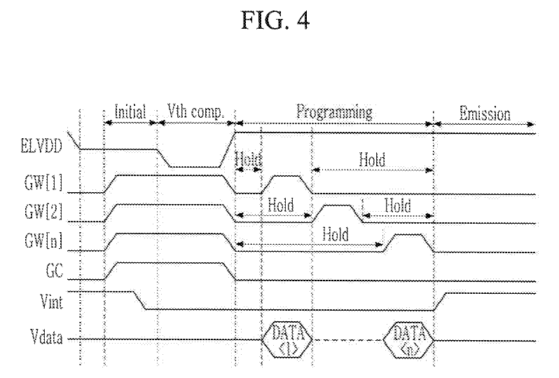

Referring to FIGS. 3 and 4 along with the previously described figures, an example of the structure of the pixel circuit portion of a pixel PX included in a display device according to an embodiment, the plurality of light-emitting elements connected to it, and the driving method will be described.

FIG. 3 is a circuit diagram of one pixel of a display device according to an embodiment. FIG. 4 is a timing diagram of signals applied to the pixel shown in FIG. 3.

A pixel PX of a display device according to an embodiment may include a first circuit portion PX-C1, a second circuit portion PX-C2, and a plurality of light-emitting elements ED1, ED2, and ED3. The first circuit portion PX-C1 and the second circuit portion PX-C2 are collectively referred to as a pixel circuit portion PX-C. The first circuit portion PX-C1 may include a plurality of transistors T1, T2, and T3 and a plurality of capacitors Cst and Cpr, and the second circuit portion PX-C2 may include a plurality of control transistors T4, T5, and T6.

The plurality of transistors T1, T2, and T3 of the first circuit portion PX-C1 may include a first transistor T1, a second transistor T2, and a third transistor T3, and the plurality of capacitors Cst and Cpr may include a storage capacitor Cst and an input capacitor Cpr. The plurality of transistors T1, T2, and T3 may be n-type transistors or p-type transistors.

The first transistor T1 changes the voltage applied to the gate electrode according to the data voltage Vdata, and accordingly can transmit a driving current to each light-emitting element ED1, ED2, and ED3 through the second circuit portion PX-C2. The gate terminal of the first transistor T1 is connected to the storage capacitor Cst, the first terminal may be connected to a first voltage line VL1 that transmits a driving voltage ELVDD (also referred to as a first driving voltage hereinafter) to receive the first driving voltage ELVDD, and the second terminal may be connected to the second circuit portion PX-C2.

In an embodiment, the first circuit portion PX-C1 may function as a common current source for the plurality of light-emitting elements ED1, ED2, and ED3 included in one pixel PX. By controlling the amount of current delivered to each light-emitting element indirectly through the control transistors of the second circuit portion PX-C2, the first circuit portion PX-C1 can maintain stable current driving characteristics and reduce the circuit area needed for multiple color sub-pixels. This configuration may support high-resolution displays while efficiently using the available circuit area.

Between the gate terminal and the second terminal of the first transistor T1, the second transistor T2 and the third transistor T3 may be connected. An input capacitor Cpr may be connected to the intermediate terminal where the second transistor T2 and the third transistor T3 are connected. Hereinafter, the intermediate terminal of the second transistor T2 and the third transistor T3 to which the input capacitor Cpr is connected is referred to as a data voltage input terminal.

The second transistor T2 may be disposed between the gate terminal of the first transistor T1 and the data voltage input terminal. The first terminal of the second transistor T2 may be connected to the data voltage input terminal to receive the data voltage, and the second terminal may be connected to the gate terminal of the first transistor T1 and the storage capacitor Cst. The gate terminal of the second transistor T2 may be connected to a first gate line SLw to receive a first gate signal GW.

The third transistor T3 may be disposed between the second terminal of the first transistor T1 and the data voltage input terminal. The first terminal of the third transistor T3 is connected to the second terminal of the first transistor T1 and the input terminal of the second circuit portion PX-C2, and the second terminal may be connected to the data voltage input terminal and connected to the first terminal of the second transistor T2. The gate terminal of the third transistor T3 may be connected to a second gate line SLc to receive a second gate signal GC.

The first gate line SLw and the second gate line SLc may each be included in the gate lines GL described above.

The second transistor T2 can transmit the data voltage transferred through the input capacitor Cpr to the gate terminal of the first transistor T1, and the second transistor T2 and the third transistor T3 can operate together to initialize the voltage of the gate terminal of the first transistor T1 and enable the threshold voltage to be stored in the storage capacitor Cst.

The storage capacitor Cst can store and maintain the data voltage transmitted to the gate terminal of the first transistor T1 through the second transistor T2. The first terminal of the storage capacitor Cst is connected to the gate terminal of the first transistor T1 and the second terminal of the second transistor T2, and the second terminal of the storage capacitor Cst may be connected to an initialization voltage line INL that transmits an initialization voltage Vint to receive the initialization voltage Vint.

The input capacitor Cpr can electrically connect the data line DL to the data voltage input terminal. The first terminal of the input capacitor Cpr is connected to the data voltage input terminal, and the second terminal of the input capacitor Cpr may be connected to the data line DL. Due to the input capacitor Cpr, the voltage of the data voltage input terminal may also change according to the voltage change of the data line DL, and the second transistor T2 may be turned on to transmit the data voltage of the corresponding pixel PX to the gate terminal of the first transistor T1. At this time, because it passes through the input capacitor Cpr, the amount of voltage change occurring at the data voltage input terminal may be reduced compared to the amount of data voltage Vdata change occurring at the data line DL. That is, a lower voltage value than the data voltage Vdata transmitted by the data line DL may be transmitted to the data voltage input terminal. For convenience of description, the term data voltage is used hereinafter for the voltage transmitted to the data voltage input terminal as well. However, for distinction, it may be named separately as the data voltage Vdata of the data line DL and the data voltage of the data voltage input terminal. Also, the data voltage of the data voltage input terminal may also be referred to as the data voltage transmitted through the input capacitor Cpr. Also, even when the data voltage transmitted to the data voltage input terminal is transmitted to the gate terminal of the first transistor T1 and the storage capacitor Cst through the second transistor T2, the term data voltage may be used for convenience of description. For distinction, it may also be expressed as the data voltage of the gate terminal of the first transistor T1 or the data voltage stored in the storage capacitor Cst.

The plurality of control transistors T4, T5, and T6 of the second circuit portion PX-C2 may include a fourth control transistor T4, a fifth control transistor T5, and a sixth control transistor T6. The number of transistors included in the second circuit portion PX-C2 may vary depending on the number of sub-pixels SP1, SP2, and SP3 included in one pixel PX. The plurality of control transistors T4, T5, and T6 may be n-type transistors or p-type transistors.

The input terminals of the plurality of control transistors T4, T5, and T6 may be connected to the second terminal of the first transistor T1 of the first circuit portion PX-C1 to receive a driving current.

In an embodiment, the second circuit portion PX-C2 may operate in cooperation with an emission control unit EMS (described further below) to selectively activate one of the control transistors T4, T5, or T6 during each sub-frame. This configuration may enable sequential operation of each light-emitting element ED1, ED2, or ED3 with a shared current source, which may support time-division driving of different colors within a single pixel PX. Such selective sub-frame activation can prevent color separation artifacts and/or improve color fidelity in moving images (e.g., video).

The output terminal of each of the plurality of control transistors T4, T5, and T6 may be connected to the anode of the corresponding light-emitting element ED1, ED2, or ED3 to transmit a driving current. For example, the output terminal of the fourth control transistor T4 may be connected to the anode of the first light-emitting element ED1, the output terminal of the fifth control transistor T5 may be connected to the anode of the second light-emitting element ED2, and the output terminal of the sixth control transistor T6 may be connected to the anode of the third light-emitting element ED3.

The gate terminal of each of the plurality of control transistors T4, T5, and T6 may be connected to the corresponding emission control line EML1, EML2, or EML3 to receive an emission control signal. For example, the gate terminal of the fourth control transistor T4 may be connected to the first emission control line EML1, the gate terminal of the fifth control transistor T5 may be connected to the second emission control line EML2, and the gate terminal of the sixth control transistor T6 may be connected to the third emission control line EML3. The first to third emission control lines EML1, EML2, and EML3 may be connected to an emission control unit EMS (also referred to as an emission control circuit) to receive emission control signals generated by the emission control unit EMS. The emission control unit EMS may be disposed in the display area DA or in the peripheral area PA. If the emission control unit EMS is disposed in the peripheral area PA, it may be included in the gate drivers GDR1 and GDR2 or may be disposed in an area adjacent to the gate drivers GDR1 and GDR2. According to an embodiment, the emission control unit EMS may also be disposed on the circuit film FLM or a circuit board connected to it. The emission control unit EMS may be connected to the signal controller CTR to receive control signals.

The emission control unit EMS can transmit an emission control signal to the plurality of control transistors T4, T5, and T6 of the second circuit portion PX-C2 that can turn on only a part (for example, only one) of the plurality of control transistors T4, T5, and T6 included in the second circuit portion PX-C2 of one pixel PX in one sub-frame SF1, SF2, or SF3 among the plurality of sub-frames SF1, SF2, and SF3 of one frame 1F. According to the emission control signal, the plurality of control transistors T4, T5, and T6 of the second circuit portion PX-C2 may be turned on in a predetermined order during the plurality of sub-frames SF1, SF2, and SF3 of one frame 1F.

In an embodiment, the emission control unit EMS may coordinate its emission control signals with data signals provided by the signal controller CTR. As a result, the appropriate grayscale or color data for each sub-pixel may be applied in synchronization with the emission timing. This coordination can help maintain accurate color reproduction while avoiding overlap between sub-frames, thus contributing to a smooth, artifact-free display of moving images (e.g., video).

The plurality of light-emitting elements ED1, ED2, and ED3 included in one pixel PX may include a first light-emitting element ED1 connected to the output terminal of the fourth control transistor T4, a second light-emitting element ED2 connected to the output terminal of the fifth control transistor T5, and a third light-emitting element ED3 connected to the output terminal of the sixth control transistor T6. The plurality of light-emitting elements ED1, ED2, and ED3 may each emit light of a different color. For example, the first light-emitting element ED1 may emit light of a first color, the second light-emitting element ED2 may emit light of a second color, and the third light-emitting element ED3 may emit light of a third color.

The cathodes of the plurality of light-emitting elements ED1, ED2, and ED3 included in one pixel PX may be connected to a second voltage line VL2 that transmits a second driving voltage ELVSS (also referred to as a common voltage) to receive the second driving voltage ELVSS.

By sharing the driving current path and time-multiplexing the activation of multiple sub-pixels through a limited number of circuit components, the pixel PX according to embodiments can be designed with a reduced circuit footprint. This may allow for smaller pixel sizes and higher pixel density, which may support high-resolution displays without sacrificing the uniformity or stability of current delivery.

Referring to FIGS. 3 and 4, the operation of the first circuit portion PX-C1 of the pixel circuit portion PX-C according to signals applied to a pixel of a display device according to an embodiment will be described.

A driving period of each sub-frame SF1, SF2, or SF3 of one frame 1F of a pixel PX of a display device according to an embodiment may be divided into an initialization period (Initial), a threshold voltage compensation period (Vth Comp.), a programming period (Programming), and an emission period (Emission).

The light-emitting elements ED1, ED2, and ED3 that have been emitting light during the emission period (Emission) end their emission period as the first driving voltage ELVDD applied to the first terminal of the first transistor T1 changes from a high voltage to a first low voltage. At this time, the first low voltage may be less than or about equal to the voltage value of the second driving voltage ELVSS being applied to the cathodes of the light-emitting elements ED1, ED2, and ED3, and as a result, current does not flow in the forward direction in the light-emitting elements ED1, ED2, and ED3. According to an embodiment, the first low voltage of the first driving voltage ELVDD may have a value slightly larger than the second driving voltage ELVSS, but even in this case, it may have a voltage value that causes the voltage of the anodes of the light-emitting elements ED1, ED2, and ED3 to not be higher than the voltage of the cathodes, so that the emission period can end.

According to embodiments, by reliably terminating the emission period in the manner described above, the driving circuit can prepare for accurate initialization in the subsequent sub-frame, which may reduce the likelihood of residual charge affecting the emission of different color sub-pixels. As a result, proper color separation may be maintained and frame-to-frame artifacts may be prevented.

Subsequently, the initialization period (Initial) begins as the first gate signal GW applied to the first gate line SLw and the second gate signal GC applied to the second gate line SLc each change to a high voltage (turn-on voltage). The second transistor T2 and the third transistor T3 are turned on by the first gate signal GW and the second gate signal GC to which a turn-on voltage is applied, and the anode of the light-emitting element ED1, ED2, or ED3 selected by the emission control signal (including the second terminal of the first transistor T1), the first terminal of the input capacitor Cpr, and the first terminal of the storage capacitor Cst (including the gate terminal of the first transistor T1) are connected to each other and may change to the same voltage while sharing accumulated charges. The voltage at this time is referred to as a first connection voltage.

Subsequently, during the initialization period (Initial), the initialization voltage Vint changes to a low voltage. As a result, the voltage value of the first terminal of the storage capacitor Cst (including the gate terminal of the first transistor T1) decreases. This also causes a decrease in the voltage of the anode of the light-emitting element ED1, ED2, or ED3 selected by the emission control signal (including the second terminal of the first transistor T1) and the first terminal of the input capacitor Cpr. That is, when the initialization voltage Vint changes to a low voltage during the initialization period (Initial), the first connection voltage may change to a second connection voltage that is even lower. At this time, both the first connection voltage and the second connection voltage are less than or about equal to the voltage value of the second driving voltage ELVSS, and as a result, in an embodiment, current does not flow in the forward direction in the light-emitting elements ED1, ED2, and ED3, and the light-emitting elements ED1, ED2, and ED3 does not emit light.

Subsequently, the threshold voltage compensation period (Vth Comp.) begins as the first driving voltage ELVDD changes from the first low voltage value to a second low voltage with an even lower voltage value. When the first driving voltage ELVDD changes to the second low voltage, the voltage of the gate terminal connected to the first terminal of the first transistor T1 through a parasitic capacitance, that is, the voltage of the first terminal of the storage capacitor Cst, may also decrease. However, the second low voltage value of the first driving voltage ELVDD is sufficiently low to make the voltage of the gate terminal of the first transistor T1 turn on the first transistor T1. In the threshold voltage compensation period, as in the initialization period, the turn-on voltage of the first gate signal GW and the second gate signal GC is applied, so the second transistor T2 and the third transistor T3 remain in the turned-on state. Therefore, the first transistor T1 is in a diode-connected state where the gate terminal and the second terminal are connected to each other, and the voltage of the gate terminal has a turn-on voltage value, causing current to flow from the second terminal toward the first terminal. The second terminal of the first transistor T1 is connected to the gate terminal, and as a result, charge can escape from the gate terminal toward the first terminal, and the voltage of the gate terminal may decrease. The voltage of the gate terminal of the first transistor T1 continues to decrease, and when the voltage difference between the gate terminal and the first terminal side becomes the threshold voltage value of the first transistor T1, the first transistor T1 is turned off. At this time, the voltage value of the gate terminal of the first transistor T1 has a value that is greater than the second low voltage by the threshold voltage value of the first transistor T1, and this voltage value is stored in the first terminal of the storage capacitor Cst. If the second low voltage value is referred to as ELVDD_L2 and the threshold voltage value is referred to as Vth, the value stored in the first terminal of the storage capacitor Cst may be ELVDD_L2 + Vth. This period is referred to as the threshold voltage compensation period because a value corresponding to the threshold voltage value of the first transistor T1 is stored in the storage capacitor Cst. Here, since both the second transistor T2 and the third transistor T3 are turned on, the voltage of the first terminal of the storage capacitor Cst and the voltage of the first terminal of the input capacitor Cpr have the same value, and the voltage of the anode of the light-emitting element ED1, ED2, or ED3 selected by the emission control signal may also have the same value as the voltage of the first terminal of the storage capacitor Cst and the voltage of the first terminal of the input capacitor Cpr.

By compensating for the threshold voltage in this manner, the first circuit portion PX-C1 can maintain consistent current drive characteristics across sub-frames, even when different sub-pixels are sequentially activated. As a result, uniform brightness and color accuracy among the sub-pixels sharing the same pixel circuit portion may be achieved.

In the threshold voltage compensation period, the voltage values of the gate terminal and the second terminal of the first transistor T1 are changed to values lower than the first connection voltage and the second connection voltage in the initialization period, so they may all be less than the voltage value of the second driving voltage ELVSS. As a result, current does not flow in the forward direction in the light-emitting elements ED1, ED2, and ED3, and the light-emitting elements ED1, ED2, and ED3 do not emit light.

Subsequently, the first gate signal GW applied to the first gate line SLw and the second gate signal GC applied to the second gate line SLc are each changed to a low voltage, which is a turn-off voltage, and the first driving voltage ELVDD is changed from the second low voltage to a high voltage. When the first driving voltage ELVDD changes to a high voltage, the voltage of the gate terminal of the first transistor T1 may increase. That is, the value previously stored in the first terminal of the storage capacitor Cst was ELVDD_L2 + Vth, and if the high voltage value of the first driving voltage ELVDD is referred to as ELVDD_H, the value stored in the first terminal of the storage capacitor Cst has a value of ELVDD_H + Vth - a. Here, a value indicates the extent to which the voltage change value of the gate terminal is smaller than the voltage change value of the first terminal of the first transistor T1. As a result, since the voltage difference between the first terminal and the gate terminal of the first transistor T1 is lower than the threshold voltage Vth, the first transistor T1 does not output current. Also, since the second transistor T2 and the third transistor T3 are in the turned-off state, the increased voltage of the gate terminal of the first transistor T1 does not affect the anode of the light-emitting elements ED1, ED2, and ED3. Therefore, the light-emitting elements ED1, ED2, and ED3 still do not emit light.

Subsequently, the programming period (Programming) begins, during which a turn-on voltage is applied to the first gate line SLw. During the programming period (Programming), the second transistor T2 is turned on by the first gate signal GW having the turn-on voltage applied to the first gate line SLw, and the data voltage of the data voltage input terminal is transmitted to and stored in the first terminal of the storage capacitor Cst. The data voltage of the data voltage input terminal at this time is a voltage transmitted from the data line DL through the input capacitor Cpr and may have a lower voltage value than the data voltage Vdata transmitted by the data line DL. The voltage of the first terminal of the storage capacitor Cst before the programming period progresses is ELVDD_H + Vth - a, and if the data voltage of the data voltage input terminal is referred to as Vdata - b (where b indicates that a lower voltage is caused than the voltage transmitted by the data line DL), the voltage of the first terminal of the storage capacitor Cst after the programming period progresses has a value of ELVDD_H + Vth - a + Vdata - b. At this time, due to the a and b values, the voltage difference between the first terminal and the gate terminal of the first transistor T1 may still be set to be less than the threshold voltage Vth. Therefore, the first transistor T1 does not generate an output current.

According to embodiments, storing the data voltage for each sub-frame may cause the selected sub-pixel to receive the appropriate grayscale level synchronized with its emission period. This may allows for sequential color sub-pixel driving while maintaining a smooth integrated image.

In FIG. 4, the programming period (Programming) includes a hold period (Hold), and the hold period (Hold) is a period before and after the first gate signal GW applies a turn-on voltage, and each first gate line SLw may have a different hold period (Hold). The hold period (Hold) is a period during which the voltages of the storage capacitor Cst and other terminals are maintained. In FIG. 4, a plurality of gate signals GW[1] to GW[n], where n is a positive integer, is illustrated.

When the data voltage of the data voltage input terminal is stored in the first terminal of the storage capacitor Cst, the light-emitting element ED1, ED2, or ED3 selected by the emission control signal in each pixel PX emits light as the initialization voltage Vint is changed from a low voltage to a high voltage. This is referred to as the emission period (Emission).

When the initialization voltage Vint changes to a high voltage, the voltage of the first terminal of the storage capacitor Cst also increases, and the voltage difference between the first terminal and the gate terminal of the first transistor T1 becomes greater than the threshold voltage Vth, causing the first transistor T1 to emit an output current. The current output from the first transistor T1 is transmitted to the anode of the light-emitting element ED1, ED2, or ED3, and the degree of emission of the light-emitting element ED1, ED2, or ED3 changes according to the magnitude of the current.

At this time, the voltage of the gate terminal of the first transistor T1 is ELVDD_H + Vth - a + Vdata - b + c, where c represents the increased voltage value as the initialization voltage Vint changes to a high voltage. If the c value is set to a value that offsets the a value and b value, the final voltage of the gate terminal of the first transistor T1 becomes ELVDD_H + Vth + Vdata. At this time, since the first terminal of the first transistor T1 has an ELVDD_H voltage value, the voltage difference between the first terminal and the gate terminal of the first transistor T1 is Vth + Vdata, and the Vth value is used to turn on the first transistor T1, and only the remaining Vdata is used as is to determine the output current of the first transistor T1. As a result, the output current of the first transistor T1 in the pixel may be determined according to the data voltage Vdata applied to the data line DL.

Even if the threshold voltage Vth of each first transistor T1 varies, this variation may be compensated for and stored in the gate terminal of the first transistor T1 during the threshold voltage compensation period. As a result, the output current may effectively be determined by the data voltage Vdata alone. As a result, differences in the threshold voltage among first transistors T1 do not affect the emission brightness for a given data voltage in embodiments, and a consistent display quality may be maintained.

In the emission period (Emission), the selected sub-pixels SP1, SP2, and SP3 of all pixels PX can emit light at once for the same time. However, embodiments are not necessarily limited thereto, and according to an embodiment, the selected sub-pixels SP1, SP2, and SP3 of some pixels PX may emit light simultaneously.

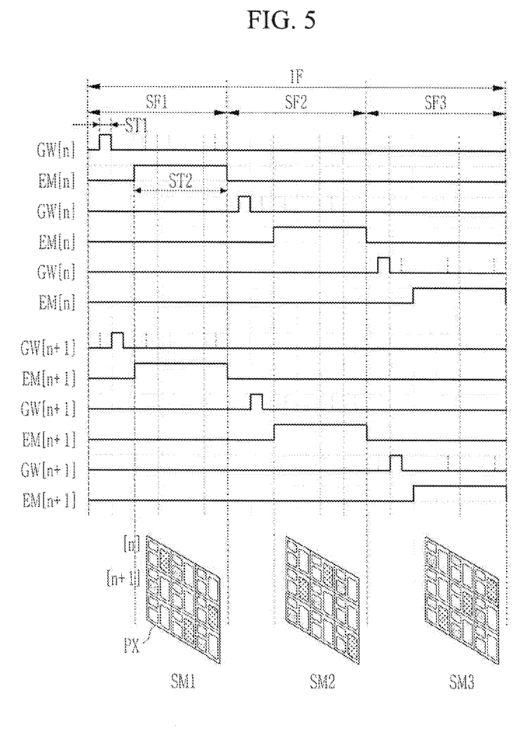

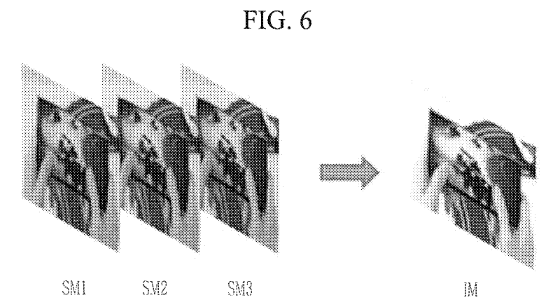

Referring to FIGS. 5 and 6 along with FIGS. 3 and 4 described above, the first gate signal GW and emission control signal EM transmitted to a plurality of pixels of a display device according to an embodiment and the image display method according to them will be described in further detail.

FIG. 5 is a diagram illustrating an image display method of sub-pixels according to signals applied to the pixel shown in FIG. 3 during one frame. FIG. 6 illustrates sub-images displayed by a display device according to an embodiment during a plurality of sub-frames and an integrated image perceived by a user.

Referring to FIG. 5, in the first sub-frame SF1 of one frame 1F, the gate drivers GDR1 and GDR2 provide first gate signals GW[n], GW[n+1], ... (where n is a positive integer) and second gate signals to a plurality of pixel rows in turn, and data voltages are transmitted to the data lines DL, so that the pixel circuit portions of the plurality of pixels PX can operate. The operation of the pixel circuit portion here can be referred to the description of FIG. 4 and the prior related description. According to the emission control signals EM[n], EM[n+1], ... of the emission control unit EMS, the light-emitting elements ED1, ED2, and ED3 connected to the turned-on control transistors T4, T5, and T6 among the plurality of control transistors T4, T5, and T6 of the second circuit portion PX-C2 of each pixel PX can emit light in the corresponding sub-frames SF1, SF2, and SF3. FIG. 5 shows an example including sub-images SM1, SM2, and SM3 represented by sub-pixels SP1, SP2, and SP3 that emit light during each sub-frame SF1, SF2, and SF3.

By synchronizing the emission control signals EM[n], EM[n+1], ... with the sub-frame timing, the display device according to embodiments can selectively activate one sub-pixel of each pixel PX in sequence, while neighboring pixels emit sub-pixels of different colors. This coordinated emission approach may suppress color break-up artifacts and support a high-resolution, high-brightness display with reduced circuit complexity, as multiple sub-pixels share the same first circuit portion PX-C1.

The width ST2 of the turn-on voltage section of the emission control signals EM[n], EM[n+1], ... may be greater than the width ST1 of the gate-on voltage pulse of the first gate signals GW[n], GW[n+1], ....

Referring to FIG. 6, each of the sub-images SM1, SM2, and SM3 displayed in the plurality of sub-frames SF1, SF2, and SF3 of one frame 1F can emit light of all colors rather than just one color, and the successively displayed sub-images SM1, SM2, and SM3 can be perceived by the user as an integrated image IM for the input image signal during one frame 1F.

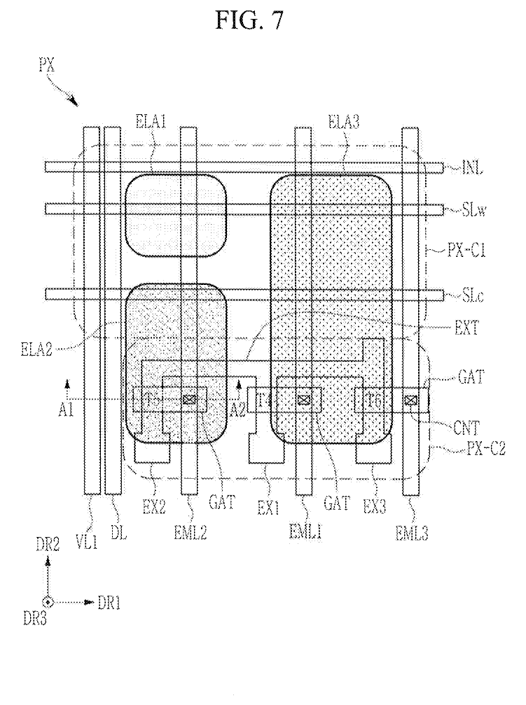

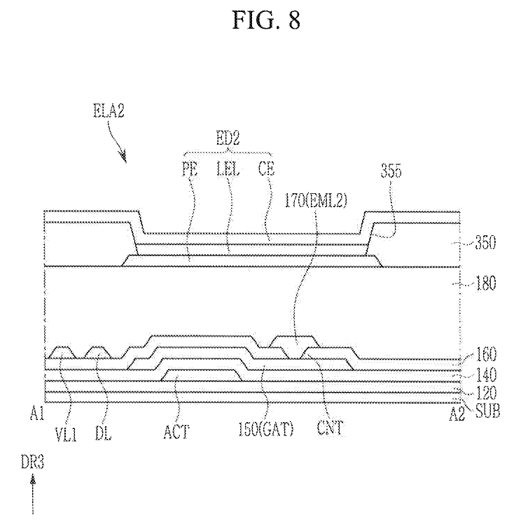

Referring to FIGS. 7 and 8 along with the previously described figures, the structure of a display device according to an embodiment will be described.

FIG. 7 is a plan view of one pixel of a display device according to an embodiment. FIG. 8 is a cross-sectional view taken along the line A1-A2 of the display device shown in FIG. 7.

Referring to FIG. 8, a display device according to an embodiment may include a substrate SUB. The substrate SUB includes an insulating material and may include, for example, glass, plastic, or the like. At least one first insulation layer 120 may be disposed on the substrate SUB. The first insulation layer 120 may include an inorganic insulating material such as, for example, silicon oxide (SiOx), silicon nitride (SiNx), or the like.

A semiconductor pattern ACT may be disposed on the first insulation layer 120. The semiconductor pattern ACT may include a semiconductor material such as, for example, amorphous silicon, polycrystalline silicon, oxide semiconductor, or the like.

Referring to FIG. 7, the semiconductor pattern ACT may include an elongated extension part EXT and a plurality of protrusion parts EX1, EX2, and EX3 protruding from the extension part EXT. The number of the plurality of protrusion parts EX1, EX2, and EX3 may vary depending on the number of the plurality of sub-pixels SP1, SP2, and SP3 included in one pixel PX. Each of the plurality of protrusion parts EX1, EX2, and EX3 may extend, for example, in the second direction DR2. The end portion of each protrusion part EX1, EX2, or EX3 may have a relatively expanded planar area. The plurality of protrusion parts EX1, EX2, and EX3 disposed in one pixel PX may be spaced apart from each other in the first direction DR1 and may be connected to one extension part EXT.

According to an embodiment, this arrangement of the extension part EXT and the plurality of protrusion parts EX1, EX2, and EX3 may allow for efficient placement of the control transistors T4, T5, and T6 in close proximity to the shared first circuit portion PX-C1, supporting the selective driving of sub-pixels SP1, SP2, and SP3 within a compact pixel area. As a result, the semiconductor pattern ACT may contribute to achieving higher pixel density while accommodating the sequential sub-frame operation described above.

Referring to FIG. 8, at least one second insulation layer 140 may be disposed on the semiconductor pattern ACT. The second insulation layer 140 may include an inorganic insulating material such as, for example, silicon oxide (SiOx), silicon nitride (SiNx), or the like.

A first conductive layer 150 may be disposed on the second insulation layer 140. The first conductive layer 150 may include a plurality of gate electrodes GAT. Each of the plurality of gate electrodes GAT may cross over and overlap in a plane with a corresponding protrusion part EX1, EX2, or EX3 of the semiconductor pattern ACT. The portion of each protrusion part EX1, EX2, or EX3 of the semiconductor pattern ACT that overlaps in a plane with each gate electrode GAT may define a channel region of each of the control transistors T4, T5, and T6. The plurality of gate electrodes GAT disposed in one pixel PX may be spaced apart from each other in the first direction DR1.

The portion of the semiconductor pattern ACT that overlaps in a plane with the gate electrode GAT may form a channel region of each control transistor T4, T5, or T6, and the portion of the semiconductor pattern ACT that does not overlap in a plane with the gate electrode GAT may form a conductive region by a doping process.

In an embodiment, by arranging the gate electrodes GAT to overlap precisely with the protrusions EX1, EX2, and EX3 of the semiconductor pattern ACT, the control transistors T4, T5, and T6 can be accurately controlled for each sub-frame, enabling selective activation of the corresponding sub-pixels SP1, SP2, and SP3. This structure may support time-division color driving with reduced area overhead, thus improving pixel density and color uniformity.

The first conductive layer 150 may include a metal such as, for example, copper Cu, molybdenum (Mo), aluminum (Al), silver (Ag), chromium (Cr), tantalum (Ta), titanium (Ti), or the like, and/or a metal alloy thereof, and may be composed of a single layer or multiple layers.

In an embodiment, at least one additional conductive layer may be disposed between the substrate SUB and the first conductive layer 150.

The first conductive layer 150, or the aforementioned at least one additional conductive layer, may include a first gate line SLw, a second gate line SLc, and an initialization voltage line INL. At least one among the first gate line SLw, the second gate line SLc, and the initialization voltage line INL may be elongated in the first direction DR1, and the first gate line SLw, the second gate line SLc, and the initialization voltage line INL may be spaced apart from each other in the second direction DR2.

Referring to FIG. 8, at least one third insulation layer 160 may be disposed on the first conductive layer 150. The third insulation layer 160 may include an inorganic insulating material such as, for example, silicon oxide (SiOx), silicon nitride (SiNx), or the like, and/or an organic insulating material.

A second conductive layer 170 may be disposed on the third insulation layer 160. The second conductive layer 170 may include a plurality of emission control lines EML1, EML2, and EML3, data lines DL, a first voltage line VL1, and the like. At least one among the plurality of emission control lines EML1, EML2, and EML3, the data lines DL, and the first voltage line VL1 may be elongated in the second direction DR2, and the plurality of emission control lines EML1, EML2, and EML3, the data lines DL, and the first voltage line VL1 may be spaced apart from each other in the first direction DR1. The plurality of emission control lines EML1, EML2, and EML3, the data lines DL, and the first voltage line VL1 may cross, while being insulated from at least one of the first gate line SLw, the second gate line SLc, and the initialization voltage line INL.

According to embodiments, by routing the plurality of emission control lines EML1, EML2, and EML3 through each pixel PX, the second circuit portion PX-C2 can selectively activate sub-pixels SP1, SP2, and SP3 according to the sub-frame schedule. This may allow for the implementation of time-division color emission with reduced routing overhead, which may reduce circuit area and improve pixel density.

The first to third emission control lines EML1, EML2, and EML3 may pass through each pixel PX. The first emission control line EML1 may be electrically connected to the gate electrode GAT crossing the protrusion part EX1 via a contact hole CNT of the third insulation layer 160, the second emission control line EML2 may be electrically connected to the gate electrode GAT crossing the protrusion part EX2 via a contact hole CNT of the third insulation layer 160, and the third emission control line EML3 may be electrically connected to the gate electrode GAT crossing the protrusion part EX3 via a contact hole CNT of the third insulation layer 160. Thereby, the fourth control transistor T4 may be controlled by the emission control signal of the first emission control line EML1, the fifth control transistor T5 may be controlled by the emission control signal of the second emission control line EML2, and the sixth control transistor T6 may be controlled by the emission control signal of the third emission control line EML3.

According to embodiments, the connection of each emission control line to its corresponding gate electrode may allow for precise timing of sub-pixel activation across sub-frames, which may aid in synchronizing color transitions and reducing artifacts in moving images (e.g., video).

The second conductive layer 170 may include a metal such as, for example, copper (Cu), molybdenum (Mo), aluminum (Al), silver (Ag), chromium (Cr), tantalum (Ta), titanium (Ti), or the like, and/or or a metal alloy thereof, and may be composed of a single layer or multiple layers.

Still referring to FIG. 8, at least one fourth insulation layer 180 may be disposed on the second conductive layer 170. The fourth insulation layer 180 may include an inorganic insulating material such as, for example, silicon oxide (SiOx), silicon nitride (SiNx), or the like, and/or an organic insulating material. The organic insulating material may include, for example, a general-purpose polymer such as Polymethylmethacrylate (PMMA) or Polystyrene (PS), polymer derivatives having phenolic groups, acrylic polymers, imide-based polymers, polyimides, acrylic polymers, siloxane-based polymers, or the like.

Between the substrate SUB and the fourth insulation layer 180, a first circuit portion PX-C1 including at least one semiconductor layer, at least one insulation layer, and at least one conductive layer may be formed. The first circuit portion PX-C1 may be electrically connected to the first gate line SLw, the second gate line SLc, the initialization voltage line INL, the data line DL, and the first voltage line VL1.

The second circuit portion PX-C2 may be disposed at a position adjacent to the first circuit portion PX-C1 in a plan view. The second circuit portion PX-C2 may include the fourth to sixth control transistors T4, T5, and T6 described above. The first to third emission control lines EML1, EML2, and EML3 may be elongated to extend to the peripheral area PA.

According to embodiments, by disposing the second circuit portion PX-C2 adjacent to the first circuit portion PX-C1 in a compact layout, the pixel circuit portion PX-C can be more easily integrated within a reduced pixel pitch, which may result in higher resolution while supporting sequential sub-frame operation.

Still referring to FIG. 8, a plurality of pixel electrodes PE may be disposed on the fourth insulation layer 180. Each pixel electrode PE may function as an anode of the corresponding light-emitting element ED1, ED2, or ED3. Each pixel electrode PE may be disposed corresponding to the first to third emission areas ELA1, ELA2, and ELA3 shown in FIG. 7. The first emission area ELA1 is the emission area of the first sub-pixel SP1 described above, the second emission area ELA2 is the emission area of the second sub-pixel SP2 described above, and the third emission area ELA3 may be the emission area of the third sub-pixel SP3 described above. Each pixel electrode PE may be electrically connected to each protrusion part EX1, EX2, or EX3 forming the output terminal of the corresponding control transistor T4, T5, or T6 of the second circuit portion PX-C2 to receive the output current of the first transistor T1.

A pixel insulation layer 350 may be disposed on the pixel electrode PE. The pixel insulation layer 350 is also referred to as a bank or a pixel defining layer. The pixel insulation layer 350 may have a pixel opening 355 disposed on the pixel electrode PE. The pixel opening 355 may define the emission areas ELA1, ELA2, and ELA3 of each sub-pixel SP1, SP2, and SP3. Each emission area ELA1, ELA2, and ELA3 may have different planar sizes depending on the color represented by the sub-pixel SP1, SP2, or SP3.

A light emitting layer LEL may be disposed inside the pixel opening 355. The light emitting layer LEL may include at least one among, for example, organic light-emitting materials, inorganic light-emitting materials, or quantum dots which may be semiconductor nanocrystals. In an embodiment, a common layer may be disposed above and/or below the light-emitting layer LEL. The common layer may also include a portion disposed on the upper surface of the pixel insulation layer 350 outside the pixel opening 355.

A common electrode CE may be disposed on the light emitting layer LEL and the pixel insulation layer 350. The common electrode CE may function as a cathode of each light-emitting element ED1, ED2, and ED3. The common electrode CE may receive the second driving voltage ELVSS.

The pixel electrode PE, the light emitting layer LEL, and the common electrode CE may together form a light-emitting element ED1, ED2, or ED3 which may be a light-emitting diode.

An encapsulation portion may be disposed on the light-emitting elements ED1, ED2, and ED3. The encapsulation portion may prevent moisture and/or oxygen from infiltrating into the light emitting layer LEL from outside the display device. The encapsulation portion may include a single layer or a single substrate, or may include at least one organic film and at least one inorganic film alternately stacked.

Touch electrodes, as well as, for example, a polarizing plate, a window, or the like may be disposed on the encapsulation portion.

According to an embodiment, the plurality of sub-pixels SP1, SP2, and SP3 included in one pixel PX can share the first circuit portion PX-C1 of one pixel circuit portion to receive driving currents. As a result, spatial efficiency may be improved and a high resolution may be achieved. Also, since different colors are displayed simultaneously in each sub-frame in a time division display method for an input image signal of one frame, degradation of display quality such as, for example, a rainbow phenomenon in which colors appear separated, can be prevented.

The display device according to embodiments of the present disclosure can be applied to various electronic devices. An electronic device according to an embodiment includes the display device described above, and may further include modules or devices having other additional functions besides the display device.

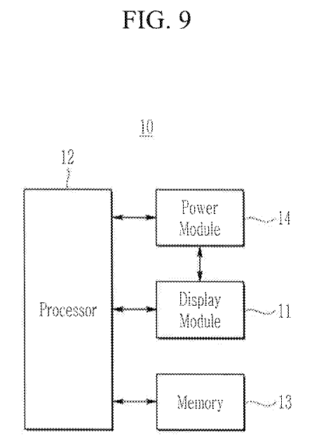

FIG. 9 is a block diagram of an electronic device according to an embodiment. Referring to FIG. 9, an electronic device 10 according to an embodiment may include a display module 11, a processor 12, a memory 13, and a power module 14. The display module may be the display device according to embodiments described above.

The processor 12 may include at least one of, for example, a central processing unit (CPU), an application processor (AP), a graphic processing unit (GPU), a communication processor (CP), an image signal processor (ISP), and a controller.

The memory 13 may store data information utilized for the operation of the processor 12 or the display module 11. When the processor 12 executes an application stored in the memory 13, image data signals and/or input control signals are transmitted to the display module 11, and the display module 11 can process the provided signals to output image information through the display screen.

The power module 14 may include a power supply module such as a power adapter or a battery device, and a power conversion module that converts power supplied by the power supply module to generate power utilized for the operation of the electronic device 10.

At least one of the components of the electronic device 10 described above may be included in the display device according to embodiments described above. Also, some of the individual modules included in one module functionally may be included in the display device, and others may be provided separately from the display device. For example, the display device may include the display module 11, and the processor 12, the memory 13, and the power module 14 may be provided in the form of other devices within the electronic device 10 that are not the display device.

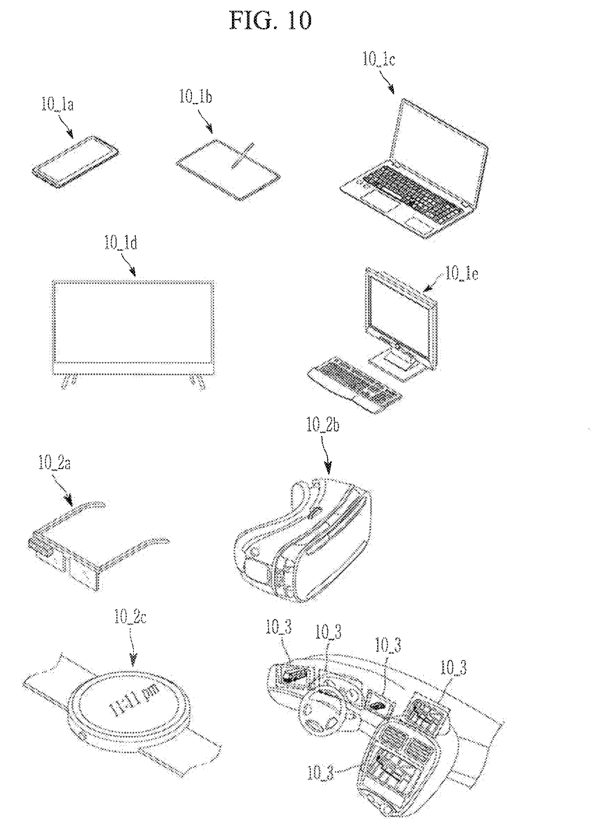

FIG. 10 is schematic diagrams of electronic devices according to various embodiments.

Referring to FIG. 10, various electronic devices to which the display device according to an embodiments is applied may include not only image display electronic devices such as smartphones 10_1a, tablet PCs 10_1b, laptops 10_1c, TVs 10_1d, and computer monitors 10_1e, but also wearable electronic devices including display modules such as smart glasses 10_2a, head-mounted displays 10_2b, and smart watches 10_2c, and vehicle electronic devices 10_3 including display modules such as instrument panels, center fascias, the center information display (CID) disposed on dashboards, and mirrors of automobiles.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a display area including a plurality of pixels;
a peripheral area disposed outside the display area;
a gate line disposed in the display area; and
a data line disposed in the display area,
wherein each of the plurality of pixels comprises:
a first circuit portion connected to the gate line and the data line;
a second circuit portion connected to the first circuit portion; and
a plurality of light-emitting elements connected to the second circuit portion and configured to emit light of different colors,
wherein the second circuit portion comprises a plurality of control transistors connected between the first circuit portion and the plurality of light-emitting elements.

2. The display device of claim 1, further comprising:
a plurality of emission control lines respectively connected to gate terminals of the plurality of control transistors; and
an emission control circuit configured to generate an emission control signal and transmit the emission control signal to the plurality of emission control lines.

3. The display device of claim 2, wherein
the emission control circuit is configured to transmit the emission control signal, which is configured to turn on only a part of the plurality of control transistors, to the second circuit portion in a first sub-frame among a plurality of sub-frames included in one frame.

4. The display device of claim 3, wherein
the plurality of control transistors of the second circuit portion are configured to be turned on sequentially during the plurality of sub-frames of the one frame according to the emission control signal.

5. The display device of claim 4, wherein
the emission control circuit is disposed outside the display area.

6. The display device of claim 4, wherein
in one of the plurality of sub-frames, a first color which is an emission color of a first light-emitting element among the plurality of light-emitting elements that emits light in a first pixel among the plurality of pixels is different from a second color which is an emission color of a second light-emitting element among the plurality of light-emitting elements that emits light in a second pixel neighboring the first pixel.

7. The display device of claim 6, wherein
a third color which is an emission color of a third light-emitting element among the plurality of light-emitting elements that emits light in a third pixel neighboring the first pixel among the plurality of pixels is different from the first color and the second color.

8. The display device of claim 6, wherein
in each of the plurality of pixels, the second circuit portion is disposed adjacent to the first circuit portion in a plan view.

9. The display device of claim 2, wherein
each of the plurality of emission control lines extends parallel to the data line.

10. The display device of claim 9, wherein
the plurality of emission control lines pass through each of the plurality of pixels.

11. An electronic device, comprising:
a processor; and
a display device connected to the processor,
wherein the display device comprises:
a display area including a plurality of pixels;
a peripheral area disposed outside the display area;
a gate line disposed in the display area; and
a data line disposed in the display area,
wherein each of the plurality of pixels comprises:
a first circuit portion connected to the gate line and the data line;
a second circuit portion connected to the first circuit portion; and
a plurality of light-emitting elements connected to the second circuit portion and configured to emit light of different colors,
wherein the second circuit portion comprises a plurality of control transistors connected between the first circuit portion and the plurality of light-emitting elements.

12. The electronic device of claim 11, further comprising:
a plurality of emission control lines respectively connected to gate terminals of the plurality of control transistors; and
an emission control circuit configured to generate an emission control signal and transmit the emission control signal to the plurality of emission control lines.

13. The electronic device of claim 12, wherein
the emission control circuit is configured to transmit the emission control signal, which is configured to turn on only a part of the plurality of control transistors, to the second circuit portion in a first sub-frame among a plurality of sub-frames included in one frame.

14. The electronic device of claim 13, wherein
the plurality of control transistors of the second circuit portion are configured to be turned on sequentially during the plurality of sub-frames of the one frame according to the emission control signal.

15. A method of driving a display device, comprising:
emitting only a part of a plurality of light-emitting elements in one sub-frame among a plurality of sub-frames included in one frame,
wherein the display device comprises a plurality of pixels, a gate line, and a data line,
wherein each of the plurality of pixels comprises a first circuit portion connected to the gate line and the data line, a second circuit portion connected to the first circuit portion, and the plurality of light-emitting elements connected to the second circuit portion and configured to emit light of different colors.

16. The method of driving a display device of claim 15, wherein
the plurality of light-emitting elements emit light sequentially during the plurality of sub-frames included in the one frame.

17. The method of driving a display device of claim 16, wherein
in one of the plurality of sub-frames, a first color which is an emission color of a first light-emitting element among the plurality of light-emitting elements that emits light in a first pixel among the plurality of pixels is different from a second color which is an emission color of a second light-emitting element among the plurality of light-emitting elements that emits light in a second pixel neighboring the first pixel.

18. The method of driving a display device of claim 17, wherein
a third color which is an emission color of a third light-emitting element among the plurality of light-emitting elements that emits light in a third pixel neighboring the first pixel among the plurality of pixels is different from the first color and the second color.

19. The method of driving a display device of claim 15, wherein
the second circuit portion comprises a plurality of control transistors connected between the first circuit portion and the plurality of light-emitting elements,
wherein emitting only the part of the plurality of light-emitting elements in the one sub-frame includes transmitting an emission control signal that turns on only a part of the plurality of control transistors to the plurality of control transistors.

20. The method of driving a display device of claim 19, further comprising:
transmitting a gate signal to the gate line before transmitting the emission control signal to the plurality of control transistors.
